(19) United States
(12) Patent Application Publication
(10) Pub. No.: US 2026/0198297 A1
(43) Pub. Date: Jul. 9, 2026

(54) SUPER SRAM CELL

(71) Applicant: TAIWAN SEMICONDUCTOR MANUFACTURING COMPANY, LTD., Hsinchu (TW)

(72) Inventors: Yi-Hsun CHIU, Hsinchu (TW); Ching-Wei TSAI, Hsinchu (TW); Chia-Tien WU, Taichung (TW); Chia Chen LEE, Taipei (TW); Ching-Chang WU, Hsinchu (TW); Kao-Cheng LIN, Taipei (TW); Yi-Bo LIAO, Hsinchu (TW)

(21) Appl. No.: 19/201,983

(22) Filed: May 8, 2025

Related U.S. Application Data
(60) Provisional application No. 63/742,048, filed on Jan. 6, 2025.

(51) Int. Cl. H01L 23/528; H01L 23/522; H10B 10/00

(52) U.S. Cl. CPC H10W 20/435; H10B 10/12; H10B 10/18; H10W 20/42

(57) ABSTRACT

Embodiments of the present disclosure provide a SRAM cell having positioning bit lines in an upper interconnect layer. In some embodiments, the bit lines of the SRAM cell are at a direction different from other conductive lines in the interconnect layer.

### CROSS-REFERENCE

This application claims priority to U.S. Provisional Patent Application No. 63/742,048 filed on Jan. 6, 2025, the entire disclosure of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Memories are commonly used in ICs. For example, a static random-access memory (SRAM) is a volatile memory used in electronic applications where high speed, low power consumption, and simplicity of operation are needed. Embedded SRAM is particularly popular in high-speed communications, image processing, and system-on-chip (SOC) applications. SRAM has the advantage of being able to hold data without requiring a refresh. An SRAM structure includes memory cells and logic cells.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a simplified diagram of an integrated circuit in accordance with some embodiments of the present disclosure.

FIG. 1B schematically illustrates an array of memory cells arranged in rows and columns according to the embodiments of the present disclosure.

FIG. 1C schematically illustrates one example of a memory bit cell according to embodiments of the present disclosure.

FIGS. 2A-2F schematically illustrate a SRAM cell according to embodiments of the present disclosure.

FIGS. 3-9 schematically illustrate SRAM cells according to other embodiments of the present disclosure.

FIGS. 10A and 10B illustrate layouts of a portion of the memory structure accordance to some embodiments of the present disclosure.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally.” “downwardly,” “upwardly.” etc.) are used for ease of the present disclosure of one features relationship to another feature. The spatially relative terms are intended to cover different orientations of the device including the features. Still further, when a number or a range of numbers is described with “about.” “approximate.” and the like, the term is intended to encompass numbers that are within +/−10% of the number described, unless otherwise specified. For example, the term “about 5 nm” encompasses the dimension range from 4.5 nm to 5.5 nm.

The present disclosure is generally related to static random-access memories (SRAM) structures including memory cells and logic cells. The memory cells are also referred to as bit cells, and are configured to store memory bits. The memory cells may be arranged in rows and columns of an array. The logic cells may be standard cells (STD cells), such as inventor (INV), AND, OR, NAND, NOR, Flip-flip, SCAN and so on. The logic cells are disposed around the memory cells, and are configured to implement various logic functions. Multilayer interconnect structures provide metal tracks (metal lines) for interconnecting power lines and signal lines between the memory cells and logic cells.

In some embodiments, conductive islands, instead of conductive lines, are formed in a first interconnect layer, which is immediately over the transistor layer. By replacing conductive lines with the conductive islands, embodiments of the present disclosure effectively reduces the parasitic capacitance in the first interconnect layer, thereby, reducing RC delay and improves speed of the memory cells. In some embodiments, bit lines of the memory cells are formed in a second interconnect layer and connected to the transistors via the conductive islands. In some embodiments, the bit lines in the second interconnect layer are formed along a first direction while conductive lines over the logic cells in the second interconnect layer are formed along a second direction.

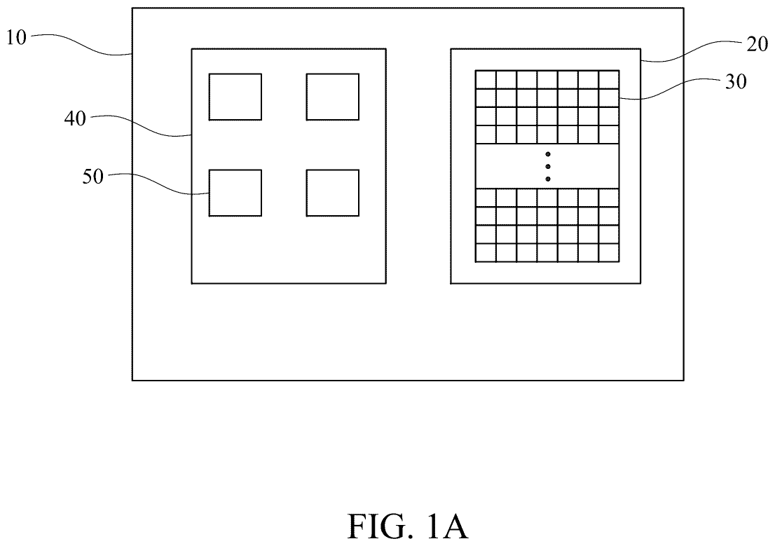

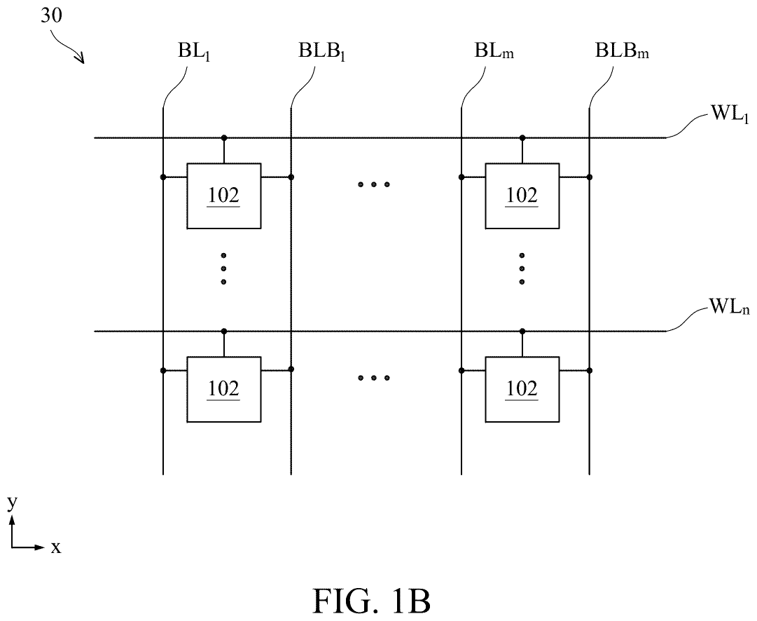

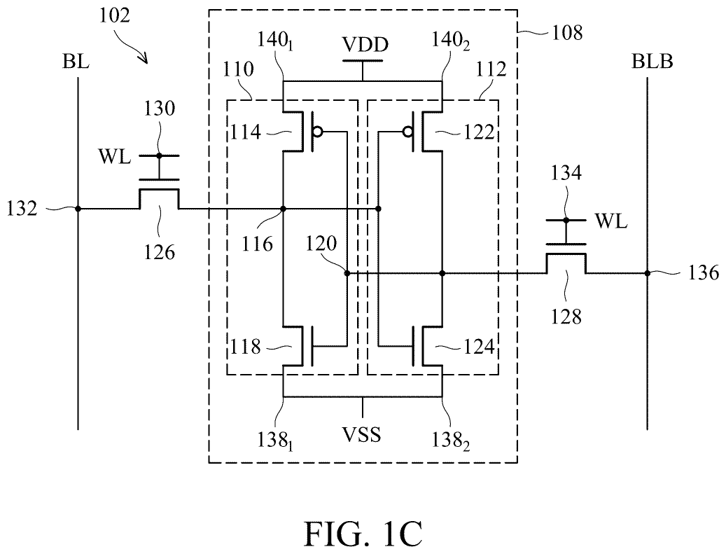

FIG. 1A is a simplified diagram of an integrated circuit 10 in accordance with some embodiments of the present disclosure. The integrated circuit 10 includes a memory circuit 20 and a logic circuit 40. The integrated circuit 10 can be, e.g., a microprocessor, an application specific integrated circuit (ASIC), a field programmable gate array (FPGA), a digital signal processor (DSP), or a portion thereof, that includes various passive and active microelectronic devices such as resistors, capacitors, inductors, diodes, p-type field effect transistors (PFETs), n-type field effect transistors (NFETs), FinFET, gate-all-around (GAA) transistors (such as nanosheet FETs or nanowire FETs), other types of multi-gate FETs, metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, memory devices, other suitable components, or combinations thereof. The exact functionality of the integrated circuit 10 is not a limitation to the provided subject matter.

The memory circuit 20 may include one or more memory array 30 of multiple memory cells arranged in rows and columns. In some embodiments, the memory cells in the memory array 30 may have the same circuit configuration and the same semiconductor structure. In some embodiments, the logic circuit 40 may be the controller for accessing the memory circuit 20.

In some embodiments, the memory circuit 20 is a static random-access memory (SRAM) memory circuit, such as a single-port SRAM circuit, a dual-port SRAM circuit, or other types of SRAM circuit. However, the present disclosure contemplates embodiments, where memory circuit 20 is another type of memory, such as a dynamic random-access memory (DRAM), a non-volatile random access memory (NVRAM), a flash memory, or other suitable memory. FIG. 1 has been simplified for the sake of clarity to better understand the inventive concepts of the present disclosure. Additional features can be added in the memory circuit 20, and some of the features described below can be replaced, modified, or eliminated in other embodiments of the memory circuit 20

In some embodiments, the logic circuit 40 includes circuits configured to perform a specific function or operation according to data stored in the memory circuit 20. The logic circuit 40 includes multiple logic cells 50. In some embodiments, the logic cell 50 may be a standard cell (STD cell), e.g., inverter (INV), AND, OR, NAND, NOR, Flip-Flop, SCAN and so on. In some embodiments, the logic cells 50 corresponding to the same function or operation may have the same circuit configuration with different semiconductor structures for providing various threshold voltages (Vth or Vt). In some embodiments, the integrated circuit 10 may be a system on chip (SOC) circuit with embedded memory circuits.

FIG. 1B schematically illustrates the memory array 30 the embodiments of the present disclosure. In some embodiments, the memory array 30 is a static random-access memory (“SRAM”) array including a plurality of bit cells 102. The bit cells 102 are arranged in a number, n, of rows and a number, m, of columns. Each bit cell 102 is coupled to a word line, WL (one of WL₁ to WLₙ), that extends horizontally across the memory array 30 (i.e., in an x-direction) and two complementary bit lines BL (one of BL₁ to BLₘ) and its complement BLB (one of BLB₁ to BLBₘ) that extend vertically across the memory array 30 (i.e., in a y-direction).

FIG. 1C is a schematic diagram of the bit cell 102 according to embodiments of the present disclosure. The bit cell 102 is a six-transistor (“6T”) SRAM cell. Each bit cell 102 includes a latch 108 formed by a pair of cross coupled inverters 110, 112. The inverter 110 includes a PMOS (p-channel metal-oxide semiconductor) transistor 114 (pull-up transistor, or PU transistor) and a NMOS (n-channel metal-oxide semiconductor) transistor 118 (pull-down transistor, or PD transistor). The PMOS transistor 114 includes a source coupled to a high-voltage source, VDD at a node 140₁, and a drain coupled to a node 116. The node 116 serves as the output of the inverter 110. The NMOS transistor 118 of the inverter 110 has a source coupled to low-voltage source VSS at a node 138₁, and a drain coupled to the node 116. Gates of the transistors 114 and 118 are coupled together at a node 120. The node 120 serves as the input of the inverter 110 and the output of the inverter 112. The inverter 112 includes a PMOS transistor 122 (pull-up transistor, or PU transistor) and a NMOS transistor 124 (pull-down transistor, or PD transistor). The PMOS transistor 122 has a source coupled to VDD at a node 140₂, a gate coupled to the node 116, and a drain coupled to the node 120. The NMOS transistor 124 has a source coupled to VSS at a node 138₂, a drain coupled to the node 120, and a gate coupled to the node 116. In some embodiment, the nodes 138₁, 138₂ are larger in dimension than the nodes 132, 136, 140₁, 140₂.

The bit cell 102 also includes a pair of pass gate transistors 126, 128 (PG transistors). In some embodiments, the pass gate transistors 126, 128 are NMOS transistors, although one skilled in the art will understand that the pass gate transistors 126, 128 may be implemented as PMOS transistors. The pass gate transistor 126 has a gate coupled to the word line WL at a node 130, a source coupled to the node 116, and a drain coupled to the bit line BL at a node 132. The transistor 128 has a gate coupled to the word line WL at a node 134, a source coupled to the node 120, and a drain coupled to the complementary bit line BLB at a node 136.

The transistors of the bit cell 102 may be formed in one or more doped regions of a semiconductor substrate using various technologies. In some embodiments, the transistors of the bit cell 102 may be GAA FETs, such as HGAA-FETs, VGAA FETs, and other suitable devices. Alternatively, the transistors of the bit cell 102 may be formed in any suitable transistors, such as bulk planar metal oxide semiconductor field effect transistors (“MOSFETs”), bulk Fin-FETs having one or more fins or fingers, semiconductor on insulator (“SOI”) planar MOSFETs, SOI Fin-FETs having one or more fins or fingers, or combinations thereof. The gates of the transistors in the bit cell 102 may include a polysilicon (“poly”)/silicon oxynitride (“SiON”) structure, a high-k/metal gate structure, or combinations thereof. Examples of the semiconductor substrate include, but are not limited to, bulk silicon, silicon-phosphorus (“SiP”), silicon-germanium (“SiGe”), silicon-carbide (“SiC”), germanium (“Ge”), silicon-on-insulator silicon (“SOI-Si”), silicon-on-insulator germanium (“SOI-Ge”), or combinations thereof.

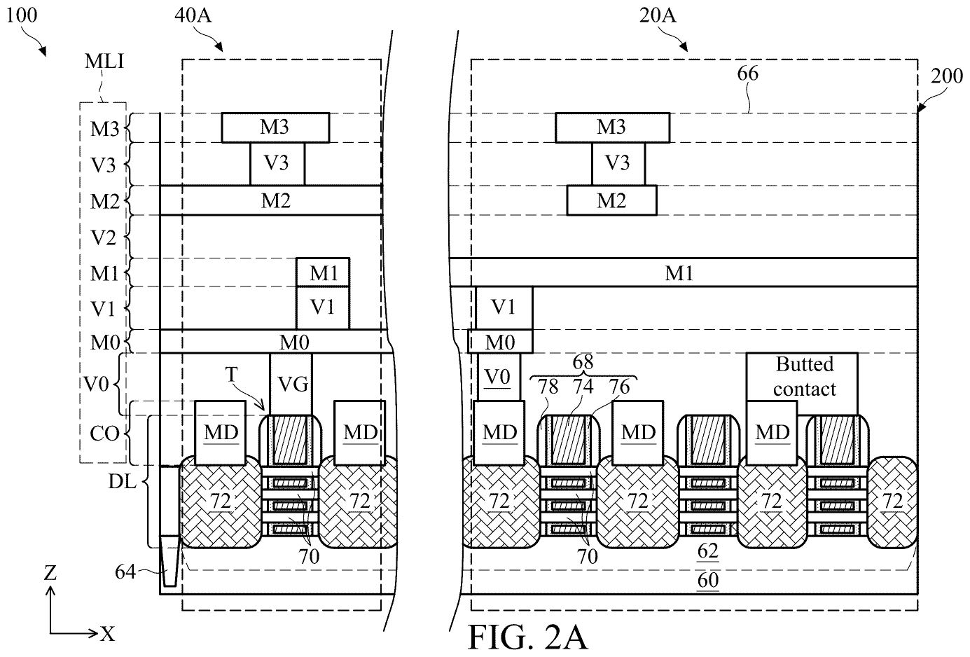

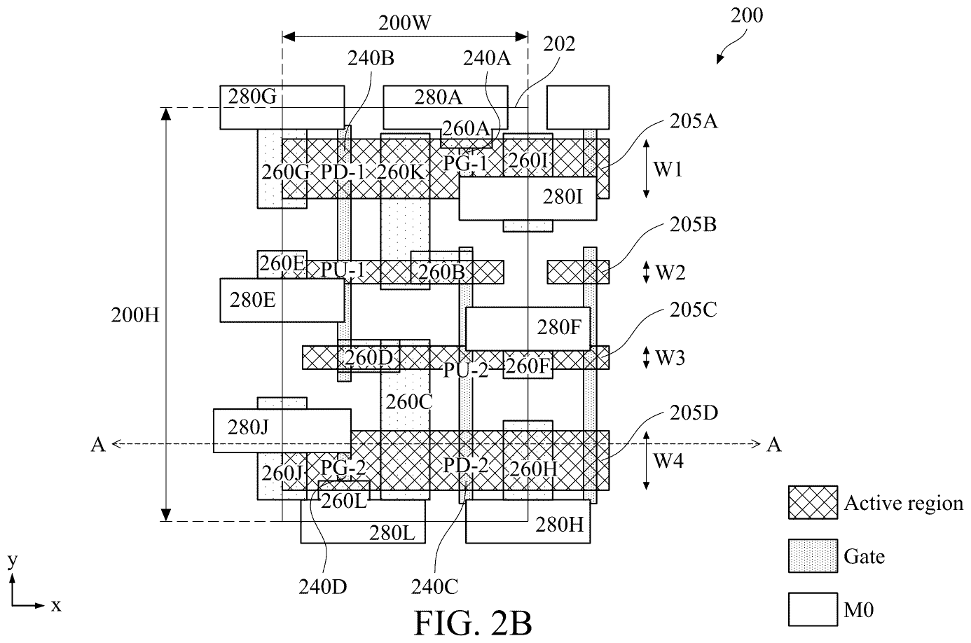

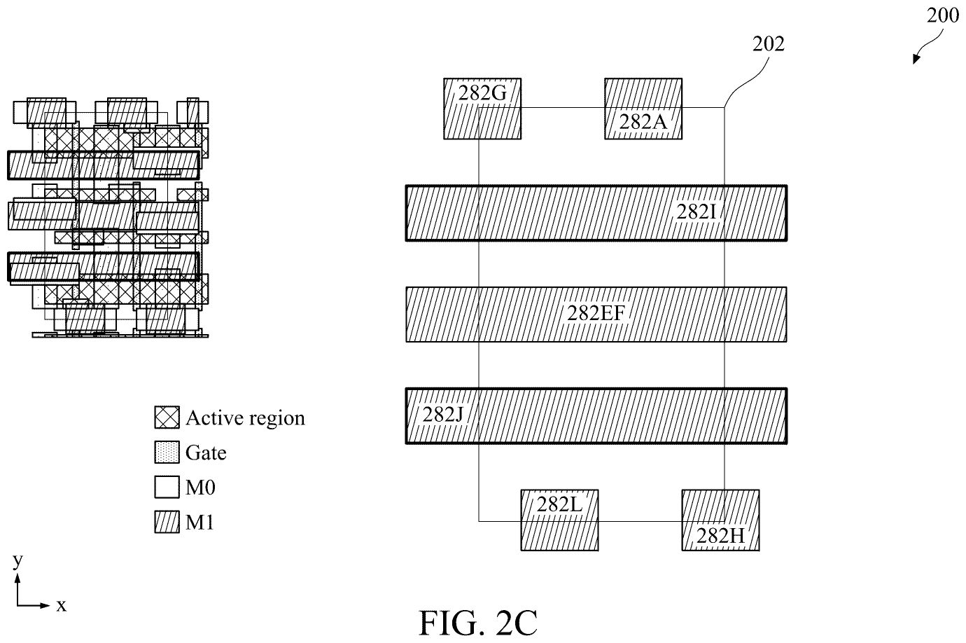

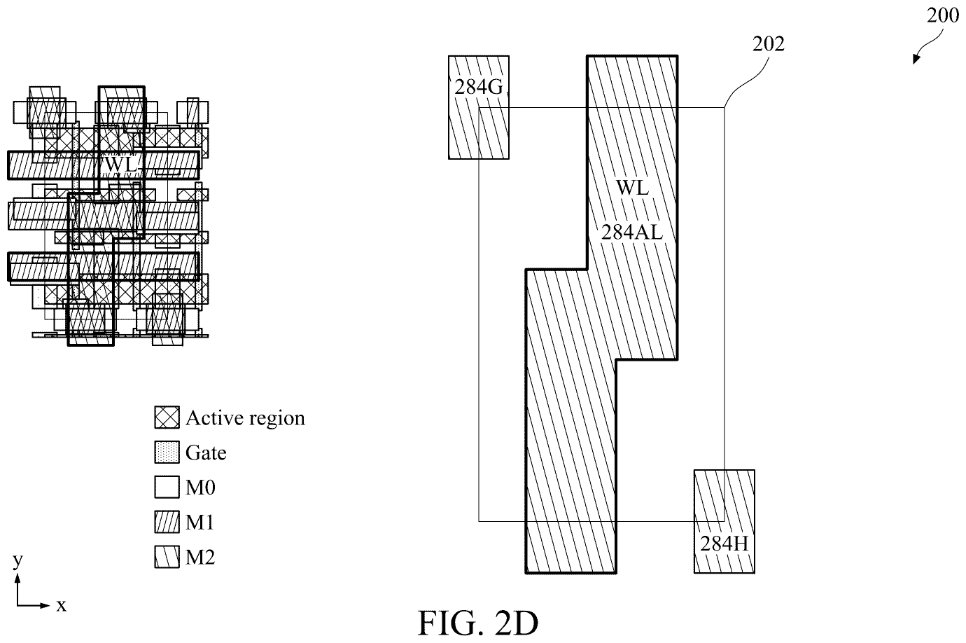

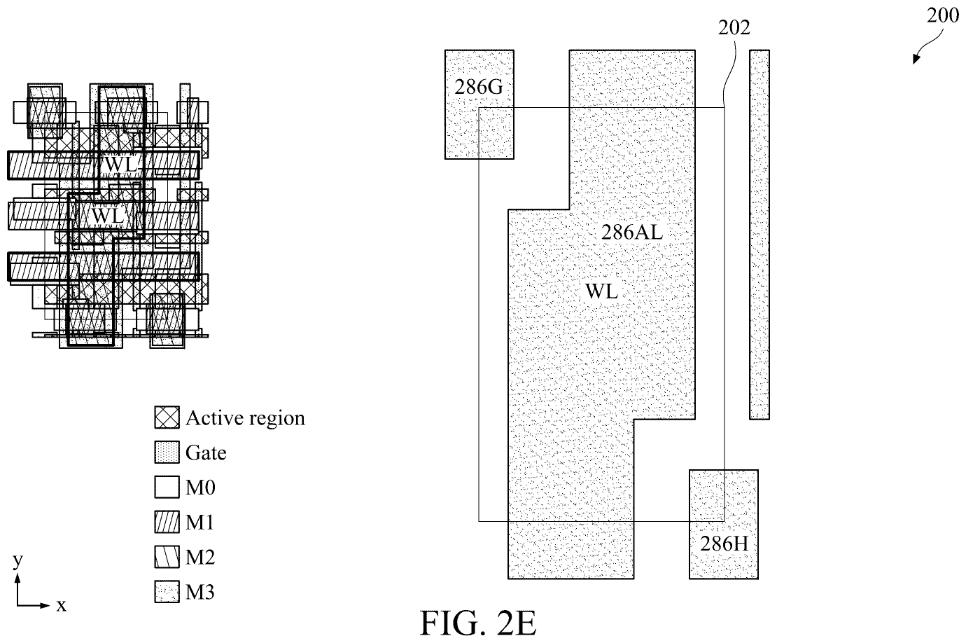

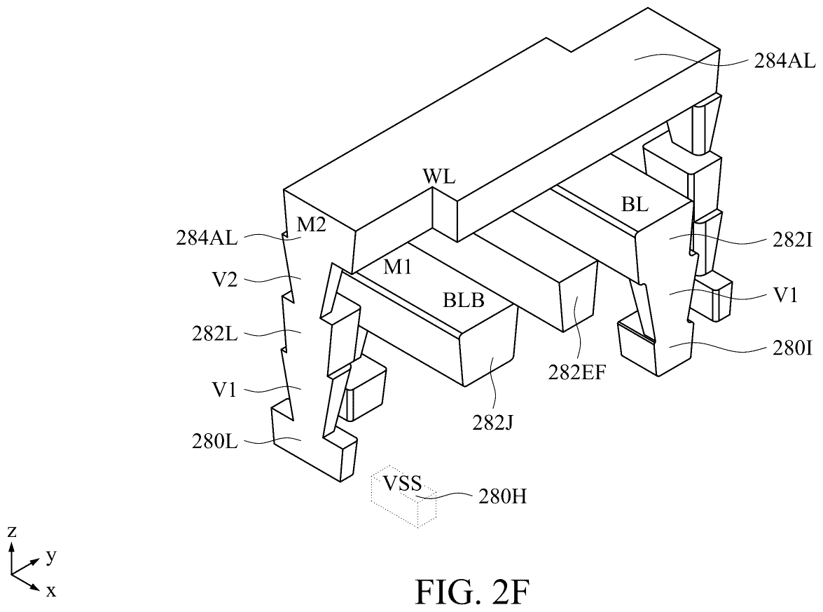

FIGS. 2A-2E schematically illustrate a SRAM cell 200 according to embodiments of the present disclosure. The SRAM cell 200 may be used to implement the bit cell 102 in FIGS. 1B-1C. FIG. 2A is a schematic cross-sectional view of various layers of a semiconductor device 100 in accordance with some embodiments of the present disclosure. The semiconductor device 100 includes SRAM cells 200 in a memory circuit region 20A and logic cells in a logic circuit region 40A. It should be noted that FIG. 2A is merely an example and may not reflect an actual cross-sectional view of the SRAM cell 200. FIG. 2A has been simplified for the sake of clarity. Additional features can be added in the various layers of the semiconductor device and the SRAM cell, and some of the features described can be replaced, modified, or eliminated in other embodiments of the semiconductor device and SRAM cells.

The semiconductor device 100 may be formed on various layers including a device layer DL and a multilayer interconnect MLI disposed over the device layer DL. The device layer DL includes devices, for example, transistors, resistors, capacitors, and/or inductors and/or device components, for example, doped wells, gate structures, and/or source/drain features. In some embodiments, device layer DL includes a substrate 60, doped regions 62 disposed in substrate 60, isolation regions 64, and transistors T. In the depicted embodiment, transistors T include channel layers 70 and gate structures 68 disposed between source/drains 72, where the gate structures 68 wrap and/or surround the channel layers 70. In FIG. 2A, the transistors T are multichannel devices including multiple channels. Alternatively, the transistors T may be FinFET or planar transistors. Each gate structure 68 includes a gate stack having a gate electrode layer 74 disposed over a gate dielectric layer 76, and gate spacers 78 disposed along sidewalls of the gate stack.

Multilayer interconnect MLI electrically couples various devices and/or components of device layer DL, such that the various devices and/or components can operate as specified by design requirements for the memory. In some embodiments, the multilayer interconnect MLI includes a contact layer (CO level), a via zero layer (V0 level), a metal zero (M0) level, a via one layer (V1 level), a metal one layer (M1 level), a via two layer (V2 level), a metal two layer (M2 level), a via three layer (V3 level), and a metal three layer (M3 level). The present disclosure contemplates multilayer interconnect MLI having more or less layers and/or levels, for example, a total number of N metal layers (levels) of the multilayer interconnect MLI with N as an integer ranging from 2 to 10.

Each level of multilayer interconnect MLI includes conductive features (e.g., metal lines, metal vias, and/or metal contacts) disposed in one or more dielectric layers (e.g., an interlayer dielectric (ILD) layer and a contact etch stop layer (CESL)). In some embodiments, conductive features at a same level of multilayer interconnect MLI, such as M0 level, are formed simultaneously. In some embodiments, conductive features at a same level of multilayer interconnect MLI have top surfaces that are substantially planar with one another and/or bottom surfaces that are substantially planar with one another.

The CO level includes source/drain contacts (MD) disposed in a dielectric layer 66; V0 level includes gate vias VG, source/drain contact vias VD, and butted contacts disposed in the dielectric layer 66; M0 level includes M0 metal lines disposed in the dielectric layer 66, where gate vias VG connect gate structures to M0 metal lines, source/drain vias V0 connect source/drains to M0 metal lines, and butted contacts connect gate structures and source/drains together and to M0 metal lines; V1 level includes V1 vias disposed in the dielectric layer 66, where V1 vias connect M0 metal lines to M1 metal lines; M1 level includes M1 metal lines disposed in the dielectric layer 66; V2 level includes V2 vias disposed in the dielectric layer 66, where V2 vias connect M1 lines to M2 lines; M2 level includes M2 metal lines disposed in the dielectric layer 66; V3 level includes V3 vias disposed in the dielectric layer 66, where V3 vias connect M2 lines to M3 lines.

Conventionally, to satisfy design rules and optimize processing and operating quality, conductive lines in multiple interconnect layer MLI in a semiconductor device are alternatively arranged in neighboring layers. For example, conductive lines in the CO level, which includes the source/drain contact MD and the gate electrode layer 74 are arranged along the y direction, i.e. into the paper, in FIG. 2A. The conductive lines in the upper layers, i.e. M0, M1, M2, M3 . . . , etc., can be alternatively arranged along the x-direction and γ-direction. In some embodiments, the conductive lines in each layer M0, M1, M2, M3 are arranged in different directions from the conductive lines in the layer immediately below and immediately above.

The device layer DL and the multilayer interconnect MLI in the memory circuit region 20A and the logic circuit region 40A are simultaneously formed layer by layer. In some embodiments, directions of the conductive lines in the multilayer interconnect MLI in the logic circuit region 40A are arranged following the design rules discussed above while at least one layer of the conductive lines in the memory circuit region 20A are arranged in deviation from the design rules. In the logic circuit region 40A, the conductive lines in the upper layers, i.e. M0, M1, M2, M3 . . . , etc., are alternatively arranged along the x-direction and γ-direction and the conductive lines in each layer M0, M1, M2, M3 are arranged in different directions from the conductive lines in the layer immediately below and immediately above. In some embodiments of the present discloser, the conductive lines in at least one levels M0, M1, and M2 are arranged along different directions between the memory circuit region 20A and the logic circuit region 40A.

For example, conductive lines in the CO level, which includes the source/drain contact MD and the gate electrode layer 74 are arranged along the y direction, i.e. into the paper, in FIG. 2A in both the memory circuit region 20A and the logic circuit region 40A. In some embodiments of the present discloser, the conductive lines in at least one levels M0, M1, and M2 are arranged along different directions between the memory circuit region 20A and the logic circuit region 40A. As shown in FIG. 2A, in level M1, the conductive lines extend along the y-direction in the logic circuit region 40A and along the x-direction in the memory circuit region 20A. In level M2, the conductive lines extend along the x-direction in the logic circuit region 40A and along the y-direction in the memory circuit region 20A. In the memory circuit region 20A, conductive lines in two adjacent layers, for example levels M2 and M3 extend along the same direction.

FIG. 2B is a schematic top view of a layout of the SRAM cell 200 in the device layer DL, the CO level above the DL level, and the M0 level above the CO level. FIG. 2C is a schematic top view of a layout of the SRAM cell 200 in the M1 level above the M0 level. FIG. 2D is a schematic top view of a layout of the SRAM cell 200 in the M2 level above the M1 level. FIG. 2E is a schematic top view of a layout of the SRAM cell 200 in the M3 level above the M2 level. FIG. 2F is a schematic three perspective view of the bit line and word line arrangement over the SRAM cell 200.

As shown in FIG. 2B, the SRAM cell 200 is defined in a cell boundary 202. The cell boundary 202 is a rectangular box. The first dimension of the cell boundary 202 along the X-direction is denoted as a cell width W, and the second dimension of the cell boundary 202 along the Y-direction is denoted as a cell height H. Where the SRAM cell 200 is repeated in a memory array, the cell width W may represent and be referred to as a memory cell pitch in the memory array along the X-direction, and the cell height H may represent and be referred to as a memory cell pitch in the memory array along the Y-direction.

The SRAM cell 200 includes active regions 205 (including active regions 205A, 205B, 205C, and 205D) that are oriented lengthwise along the X-direction, and gate structures 240 (including gate structures 240A, 240B, 240C, 240D) that are oriented lengthwise along the Y-direction perpendicular to the X-direction. The active regions 205B and 205C are disposed over an n-type well (or n-well) 204N. The active regions 205A and 205D are disposed over p-type wells (or p-wells) 204P that are on both sides of the n-well 204N along the Y-direction. The gate structures 240 engage the channel regions of the respective active regions 205 to form transistors. In that regard, the gate structure 240A engages the channel region of the active region 205A to form an n-type transistor as the pass-gate transistor PG-1; the gate structure 240B engages the channel region of the active region 205A to form an n-type transistor as the pull-down transistor PD-1 and engages the channel region of the active region 205B to form a p-type transistor as the pull-up transistor PU-1; the gate structure 240C engages the channel region of the active region 205D to form an n-type transistor as the pull-down transistor PD-2 and engages the channel region of the active region 205C to form a p-type transistor as the pull-up transistor PU-2; and the gate structure 240D engages the channel region of the active region 205D to form an n-type transistor as the pass-gate transistor PG-2.

In the present embodiment, each of the channel regions is in the form of vertically stacked nanostructures and each of the transistors PU-1, PU-2, PD-1, PD-2, PG-1, and PG-2 is a GAA transistor. Alternatively, each of the channel regions is in the form of a fin and each of the transistors PU-1, PU-2, PD-1, PD-2, PG-1, and PG-2 is a FinFET transistor.

Different active regions in different transistors of the SRAM cell 200 may have different widths (e.g., dimensions measured in the Y-direction) in order to optimize device performance. In more detail, the active region 205A of the pull-down transistor PD-1 and the pass-gate transistor PG-1 has a width W1, the active region 205B of the pull-up transistor PU-1 has a width W2, the active region 205C of the pull-up transistor PU-2 has a width W3, and the active region 205D of the pass-gate PG-2 and the pull-down transistor PD-2 has a width W4.

Gate contacts and source/drain contacts are formed at the level CO. As shown in FIG. 2B, in the level CO, contact features includes gate contacts 260A, 260B, 260D, 260L and source/drain contacts 260C, 260E, 260F, 260G, 260H, 260I, and 260J (collectively contact features 260).

In the level M0, landing pads 280A, 280E, 280F, 280G, 280H, 280I, 280J, and 280L (collectively, landing pads 280) are formed. In some embodiments, landing pads 280 are individual islands instead of conductive lines. For clarity purpose, a conductive island refers to a structure having a length substantially similar to a width. a conductive line refers to a structure having a length significantly greater than a width. For example, a line may have a length that is at least twice its width. The landing pads 280A, 280L are WL landing pads, positioned to connect with word lines at an upper MLI level, for example at level M2 or M3. The landing pads 280E, 280F are VDD landing pads. The landing pads 280G, 280H are VSS landing pads. The landing pads 280I, 280J are a bit line landing pad and a complementary bit line landing pad.

The gate contact 260A electrically connects a gate of the pass-gate transistor PG-1 (formed by gate structure 240A) to the first WL landing pad 280A. The first WL landing pad 280A is electrically coupled to a word line WL located at a higher metal level. The gate contact 260L electrically connects the gate of the pass-gate transistor PG-2 (formed by gate structure 240D) to the second word line WL landing pad 280L. The second WL landing pad 280L is electrically coupled to a word line WL located at a higher metal level.

The source/drain contact 260K electrically connects a drain region of the pull-down transistor PD-1 (formed on the active region 205A (which may include n-type epitaxial source/drain features)) and a drain region of the pull-up transistor PU-1 (formed on the active region 205B (which may include p-type epitaxial source/drain features)), such that a common drain of pull-down transistor PD-1 and pull-up transistor PU-1 form a storage node SN. The gate contact 260B electrically connects a gate of the pull-up transistor PU-2 (formed by gate structure 240C) and a gate of the pull-down transistor PD-2 (also formed by gate structure 240C) to the storage node SN. The gate contact 260B may be a butted contact abutting the source/drain contact 260K.

The source/drain contact 260C electrically connects a drain region of the pull-down transistor PD-2 (formed on the active region 205D (which may include n-type epitaxial source/drain features)) and a drain region of the pull-up transistor PU-2 (formed on the active region 205C (which may include p-type epitaxial source/drain features)), such that a common drain of pull-down transistor PD-2 and pull-up transistor PU-2 form a complementary storage node SNB. The gate contact 260D electrically connects a gate of the pull-up transistor PU-1 (formed by the gate structure 240B) and a gate of the pull-down transistor PD-1 (also formed by the gate structure 240B) to the complementary storage node SNB. The gate contact 260D may be a butted contact abutting the source/drain contact 260C.

The source/drain contact 260E electrically connects a source region of pull-up transistor PU-1 (formed on the active region 205B (which can include p-type epitaxial source/drain features)) to the first VDD landing pad 280E. The first VDD landing pad 280E is electrically coupled to a power supply voltage VDD at an upper level. The source/drain contact 260F electrically connects a source region of the pull-up transistor PU-2 (formed on the active region 205C (which may include p-type epitaxial source/drain features)) to a second VDD landing pad 280F. The second VDD landing pad 280F is electrically coupled to a power supply voltage VDD at an upper level.

The source/drain contact 260G electrically connects a source region of the pull-down transistor PD-1 (formed on the active region 205A (which may include n-type epitaxial source/drain features)) to a first VSS landing pad 280G. The first VSS landing pad 280G is electrically coupled to an electric ground VSS. The source/drain contact 260H electrically connects a source region of the pull-down transistor PD-2 (formed on the active region 205D (which may include n-type epitaxial source/drain features)) to a second VSS landing pad 280H. The second VSS landing pad 280H is electrically coupled to an electric ground VSS. The source/drain contact 260G and the source/drain contact 260H may be device-level contacts that are shared by adjacent SRAM cells 200 (e.g., four SRAM cells 200 abutting at a same corner may share one source/drain contact 260H).

The source/drain contact 260I electrically connects a source region of the pass-gate transistor PG-1 (formed on the active region 205A (which may include n-type epitaxial source/drain features)) to the bit line landing pad 280I. The bit line landing pad 280I is electrically coupled to a bit line at an upper level. The source/drain contact 260J electrically connects a source region of the pass-gate transistor PG-2 (formed on the active region 205D (which may include n-type epitaxial source/drain features)) to the complementary bit line landing pad 280J. The complementary bit line landing pad 280J is electrically coupled to a complementary bit line (bit line bar) at an upper level.

In the M0 level as shown in FIG. 2B, the bit line landing pad 280I, bit line bar landing pad 280J, VDD landing pad 280E, VSS landing pad 280G, VSS landing pad 280H, word line landing pad 280A, word line landing pad 280L have longitudinal directions substantially along the X-direction. However, instead of forming conductive lines, the conductive features in the M0 level are landing pads.

“Landing pad” generally refers to metal lines in metal layers that provide intermediate, local interconnection for the SRAM cell, such as (1) an intermediate, local interconnection between a device-level feature (e.g., gate or source/drain) and a bit line, a bit line bar, a word line, a voltage line or (2) an intermediate, local interconnection between bit lines, word lines, or voltage lines. For example, the VSS landing pad 280G is connected to source/drain contact 260G of the transistor PD-1 and further connected to a VSS line located in a higher metal level, the VSS landing pad 280H is connected to source/drain contact 260H of the transistor PD-2 and further connected to a VSS line located in a higher metal level, the WL landing pad 280A is connected to a gate of the transistor PG-1 and further connected to a word line WL located in a higher metal level, and the WL landing pad 280L is connected to a gate of the transistor PG-2 and further connected to a word line WL located in a higher metal level.

Landing pads have longitudinal dimensions that are large enough to provide a sufficient landing area for their overlying vias (and thus minimize overlay issues and provide greater patterning flexibility). In the depicted embodiment, landing pads have longitudinal dimensions that are less than dimensions of the SRAM cell 200, such as dimensions along the X-direction that are less than cell width 200 W and dimensions along the Y-direction that are less than cell height 200H.

In some embodiments, the landing pads 280 in the M0 level have a longitudinal dimension along the X-direction in a range between about 0.2 and 0.4 of the cell width 200 W of the SRAM cell 200. Compared to conductive lines, the landing pads 280 in the level M0 are positioned apart with fewer overlapping sections, therefore, with greatly reduced parasitic capacitance.

Referring to FIG. 2C, in the level M1, landing pads 282A, 282G, 282H, and 282L (collectively, landing pads 282) and a bit line 282I, a bit line bar 282J, and a VDD line 282EF are formed.

The landing pads 282A, 282L are WL landing pads, positioned to connect between the WL landing pads 280A, 280L in the M0 level and word lines at an upper MLI level, for example at level M2 or M3. The landing pads 282G, 282H are VSS landing pads. The VSS landing pad 282G is connected between the first VSS landing pad 280G in the M0 level and the electric ground VSS. The VSS landing pad 282H is connected between the second VSS landing pad 280H in the M0 level and the electric ground VSS.

The VDD line 282EF are electrically connected to the VDD landing pads 280E, 280F in the M0 level. The bit line 282I is connected to the bit line landing pad 280I in the M0 level and the bit line bar 282J is connected to the bit line bar landing pad 280J in the M0 level.

The bit line 282I, the bit line bar 282J, and the VDD line 282EF travel through the entire SRAM cell 200 along the X-direction. The bit line 282I, the bit line bar 282J, and the VDD line 282EF at the M1 level are also referred to as global metal lines, while the landing pads 282A, 282L, 282G, 282H are referred to as local metal lines. In some embodiments, a length of each of the bit line 282I, the bit line bar 282J, and the VDD line 282EF is sufficient to allow electrical connection of multiple SRAM cells in a column (or a row) to the respective global metal line.

As discussed above, conductive features in the CO level, M0 level, and higher metal levels (e.g., M1 level, M2 layer, M3 level) are routed along a first routing direction or a second routing direction that is different than the first routing direction. For example, the first routing direction is the X-direction (and substantially parallel with the lengthwise direction of active regions 205A-205D) and the second routing direction is the Y-direction (and substantially parallel with the lengthwise direction of gate structures 240A-240D). In the depicted embodiment, the source/drain contacts (260C, 260E, 260F, 260G, 260H, 260I, 260J) have longitudinal (lengthwise) directions substantially along the Y-direction (i.e., second routing direction), and butted contacts (260B, 260D) have longitudinal directions substantially along the X-direction (i.e., first routing direction). According to design rules, the conductive lines of even-numbered metal layers (i.e., M0 level and M2 level) are routed along the X-direction (i.e., the first routing direction) and conductive lines of odd-numbered metal layers (i.e., M1 level and M3 level) are routed along the Y-direction (i.e., the second routing direction).

In the embodiment of FIG. 2A, the conductive lines in the M1 level are oriented along the X-direction in the SRAM cell 200 in the memory circuit region 20A while the conductive lines in the M1 level are oriented along the y-direction in the logic circuit region 40A. The conductive lines in the M1 level in the memory circuit region 20A, i.e. the bit line 282I, the bit line bar 282J, and the VDD line 282EF, extend along the “wrong way” with respect to the conductive lines in the same level in the logic circuit region 40A and the conductive lines in the M0 level.

Referring to FIG. 2D, in the level M2, landing pads 284G, 284H and a word line 284AL are formed. The landing pads 284G, 284H are VSS landing pads. The VSS landing pad 284G is connected between the VSS landing pad 282G in the M1 level and the electric ground VSS. The VSS landing pad 284H is connected between the VSS landing pad 282H in the M1 level and the electric ground VSS.

The word line 284AL are electrically connected to the WL landing pads 282A, 282L in the M1 level. The word line 284AL travels through the entire SRAM cell 200 along the Y-direction. In some embodiments, a length the word line 284AL is sufficient to allow electrical connection of multiple SRAM cells in a row (or a column) to the respective global metal line. In some embodiments, the word line 284AL includes two staggered segments extending along the Y-direction and connected near a center of the SRAM cell 200.

In the embodiment of FIG. 2A, the conductive lines in the M2 level are oriented along the Y-direction in the SRAM cell 200 in the memory circuit region 20A while the conductive lines in the M2 level are oriented along the X-direction in the logic circuit region 40A. The conductive lines in the M2 level in the memory circuit region 20A, i.e. word line 284AL, extend along the “wrong way” with respect to the conductive lines in the same level in the logic circuit region 40A.

Referring to FIG. 2E, in the level M3, landing pads 286G, 286H and a word line 286AL are formed. The landing pads 286G, 286H are VSS landing pads. The VSS landing pad 286G is connected between the VSS landing pad 284G in the M2 level and the electric ground VSS. The VSS landing pad 286H is connected between the VSS landing pad 284H in the M2 level and the electric ground VSS.

The word line 286AL are electrically connected to the word line 284AL in the M2 level (by vias). The word line 286AL travels through the entire SRAM cell 200 along the Y-direction. In some embodiments, a length the word line 286AL is sufficient to allow electrical connection of multiple SRAM cells in a row (or a column) to the respective global metal line. In some embodiments, the word line 286AL includes two staggered segments extending along the Y-direction and connected near a center of the SRAM cell 200.

In the embodiment of FIG. 2A, the conductive lines in the M2 level and M3 level are oriented along the same direction, the Y-direction, in the SRAM cell 200 in the memory circuit region 20A. The word lines 286AL and 284AL are parallelly connected, therefore, creating a combined word line with reduced resistance. In some embodiments, the word line 286AL in the M3 level may be omitted.

FIG. 2F schematically illustrates the arrangement of the word line 284AL, the bit line 282I, the bit line bar 282J, and the VDD line 282EF in the SRAM cell 200. The bit line 282I and bit line bar 282J are positioned in the M1 level. Conventionally, bit lines for SRAM cells are located in the M0 level to satisfy design rules and to have the bit lines extend along the same direction of the active regions. As the dimension shrinks, the distance between bit lines and the transistors reduces and generating increased parasitic capacitance. By positioning the bit lines 282I, 282J at the M1 level, parasitic capacitance is reduced.

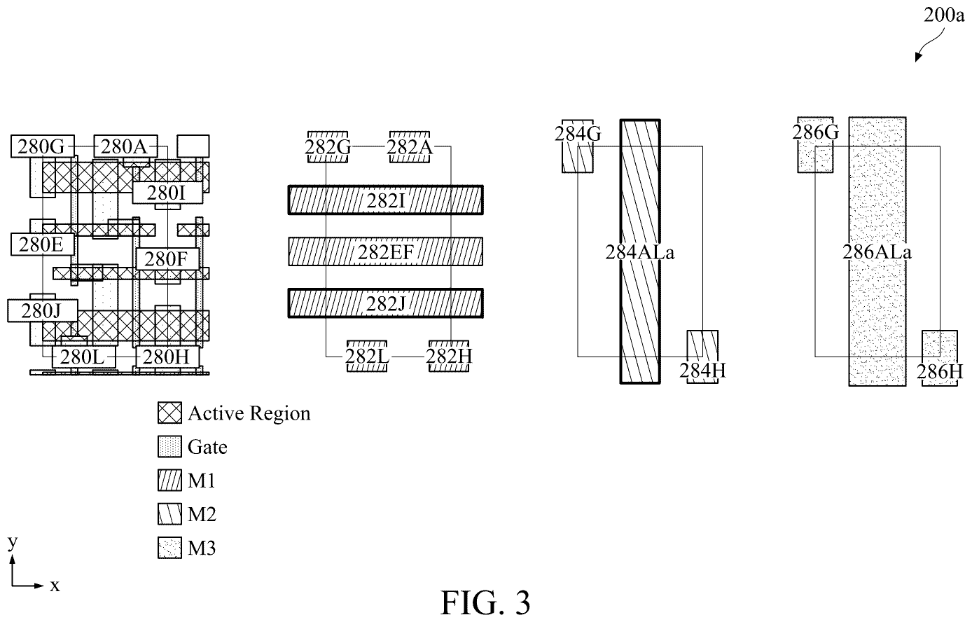

The SRAM cell according to the present disclosure may have variation. FIGS. 3-9 schematically illustrate SRAM cells according to other embodiments of the present disclosure.

FIG. 3 schematically illustrates a SRAM cell 200a according to embodiments of the present disclosure. Particularly, FIG. 3 illustrates side-by-side layouts of the SRAM cell 200a in the M0, M1, M2, and M3 levels. The SRAM cell 200a is similar to the SRAM cell 200 except that the SRAM cell 200a includes word lines in straight lines. As shown in FIG. 3, in the M2 level, the SRAM cell 200a includes a word line 284ALa, which is a straight conductive line extends along the Y-direction. Similarly, in the M3 level, the SRAM cell 200a includes a word line 286ALa, which is a straight conductive line extends along the Y-direction.

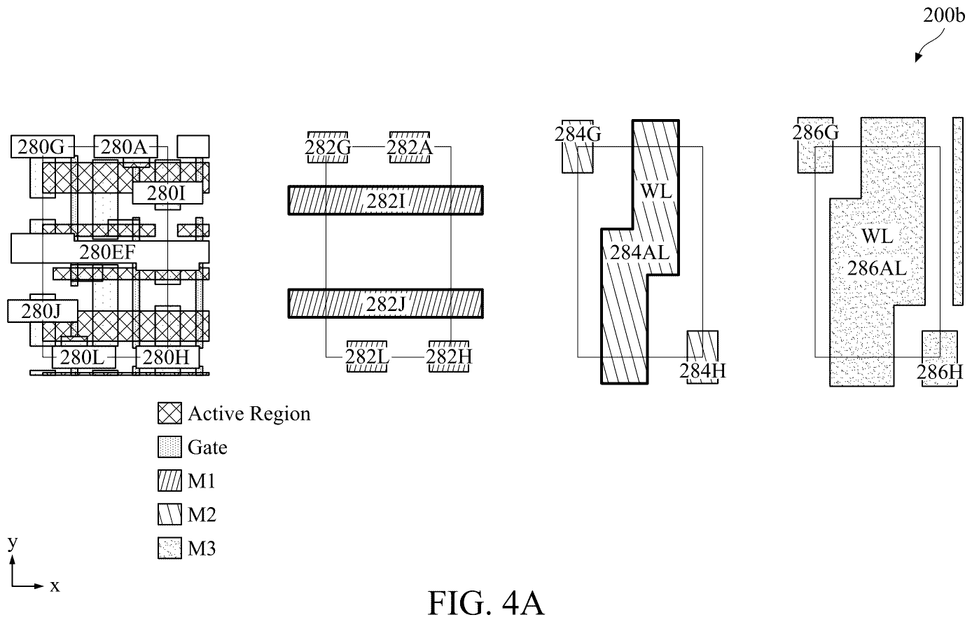

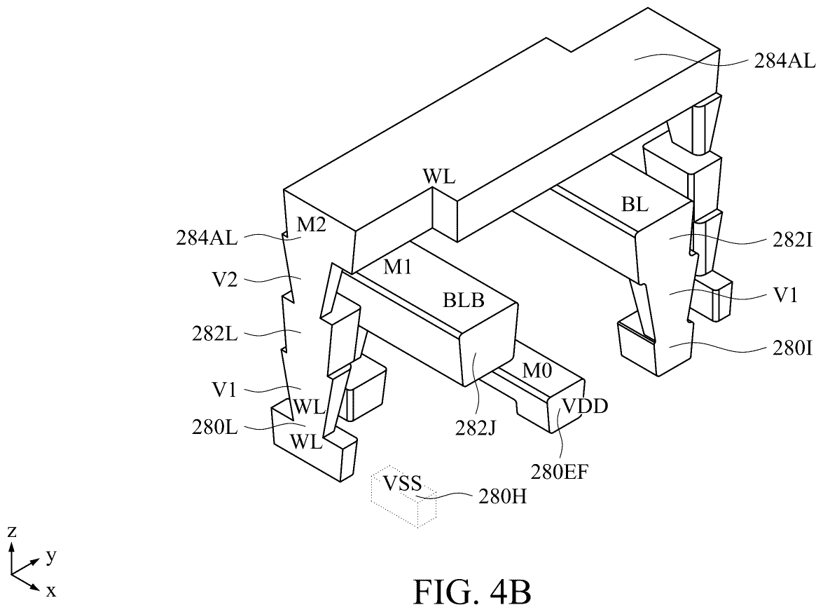

FIG. 4A schematically illustrates a SRAM cell 200b according to embodiments of the present disclosure. Particularly, FIG. 4A illustrates side-by-side layouts of the SRAM cell 200b in the M0, M1, M2, and M3 levels. The SRAM cell 200b is similar to the SRAM cell 200 except that in the SRAM cell 200, VDD line is positioned in the M0 level. In the M0 level, the SRAM cell 200b includes a VDD line 280EF in place of the VDD landing pads 280E, 280F in the SRAM cell 200. The VDD line 280EF extends along the X-direction. In the M1 level, the bit line 282I and the bit line bar 282J are positioned side-by-side. This arrangement provides a larger area for the bit line 282I and the bit line bar 282J, thus, a reduced resistance in the bit line 282I and the bit line bar 282J.

FIG. 4B schematically illustrates the arrangement of the word line 284AL, the bit line 282I, the bit line bar 282J, and the VDD line 280EF in the SRAM cell 200b. The bit line 282I and bit line bar 282J are positioned in the M1 level while the VDD line 280EF is posited in the M0 level.

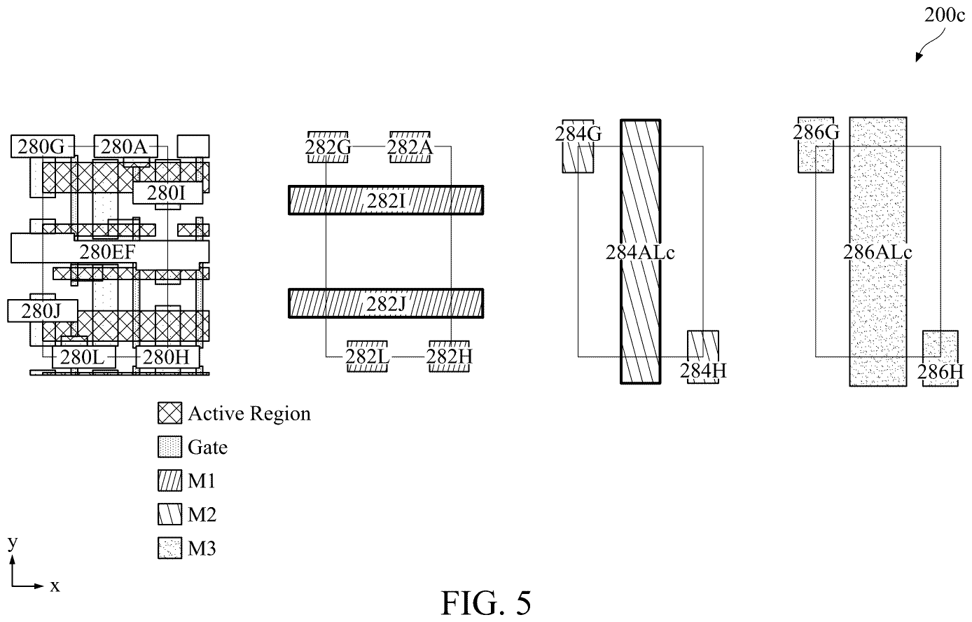

FIG. 5 schematically illustrates a SRAM cell 200c according to embodiments of the present disclosure. Particularly, FIG. 5 illustrates side-by-side layouts of the SRAM cell 200c in the M0, M1, M2, and M3 levels. The SRAM cell 200c is similar to the SRAM cell 200b except that the SRAM cell 200c includes word lines in straight lines. As shown in FIG. 5, in the M2 level, the SRAM cell 200c includes a word line 284ALc, which is a straight conductive line extends along the Y-direction. Similarly, in the M3 level, the SRAM cell 200c includes a word line 286AL, which is a straight conductive line extends along the Y-direction.

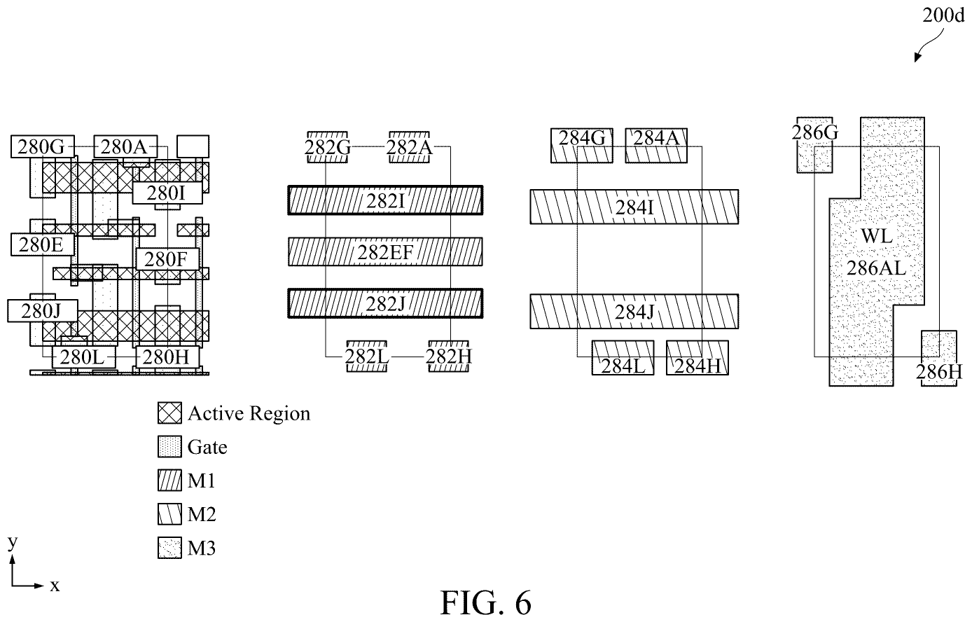

FIG. 6 schematically illustrates a SRAM cell 200d according to embodiments of the present disclosure. Particularly, FIG. 6 illustrates side-by-side layouts of the SRAM cell 200d in the M0, M1, M2, and M3 levels. The SRAM cell 200d is similar to the SRAM cell 200 except that the SRAM cell 200d includes bit lines in the M2 level. As shown in FIG. 6, in the M2 level, the SRAM cell 200d includes a bit line 2841 and a bit line bar 284J, which is a straight conductive line extends along the X-direction. The bit line 2841 and bit line bar 284J are connected to the bit line 282I and bit line bar 282J in the M1 level respectively. The bit lines 282I, 2841 are connected in parallel, thus, further reduce resistance of the bit line in the SRAM cell 200d. Similarly, the bit line bars 282J, 284J are connected in parallel, thus, further reduce resistance of the bit line bar in the SRAM cell 200d. The SRAM cell 200d further includes WL landing pads 284A, 284L in the M2 level. The WL landing pads 284A and 284L electrically connects the WL landing pads 282A, 282L in the M1 level to the word line 286AL in the M3 level.

In the arrangement of the SRAM cell 200d, the conductors in the M2 level follow the design rules, extending along the X-direction. As shown in FIG. 6, the landing pads 284A, 284G, 284H, 284L may also extend along the X-direction.

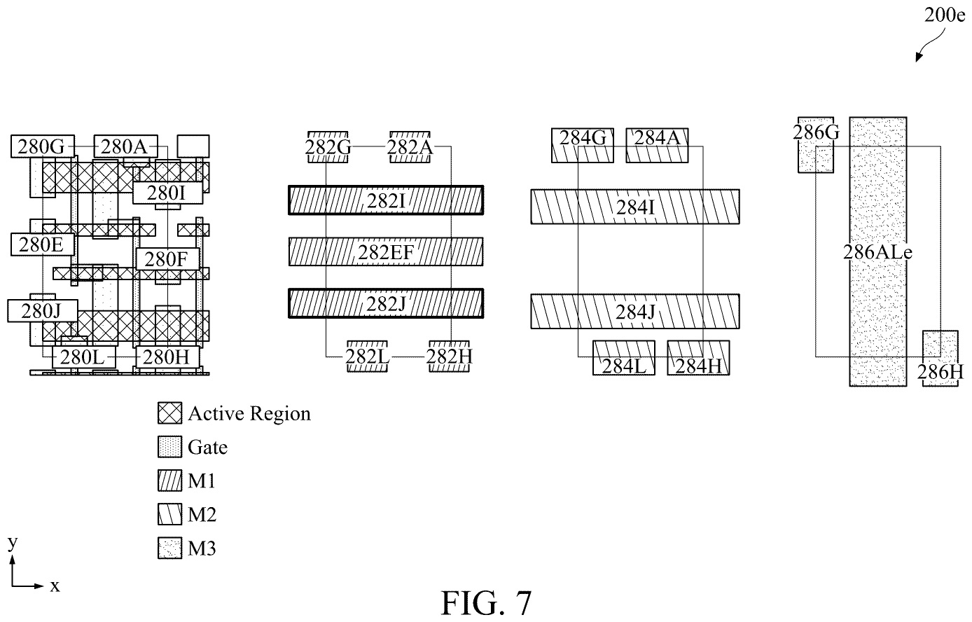

FIG. 7 schematically illustrates a SRAM cell 200e according to embodiments of the present disclosure. Particularly, FIG. 7 illustrates side-by-side layouts of the SRAM cell 200e in the M0, M1, M2, and M3 levels. The SRAM cell 200e is similar to the SRAM cell 200d except that the SRAM cell 200e includes word lines in straight lines. As shown in FIG. 7, in the M3 level, the SRAM cell 200e includes a word line 286ALe, which is a straight conductive line extends along the Y-direction.

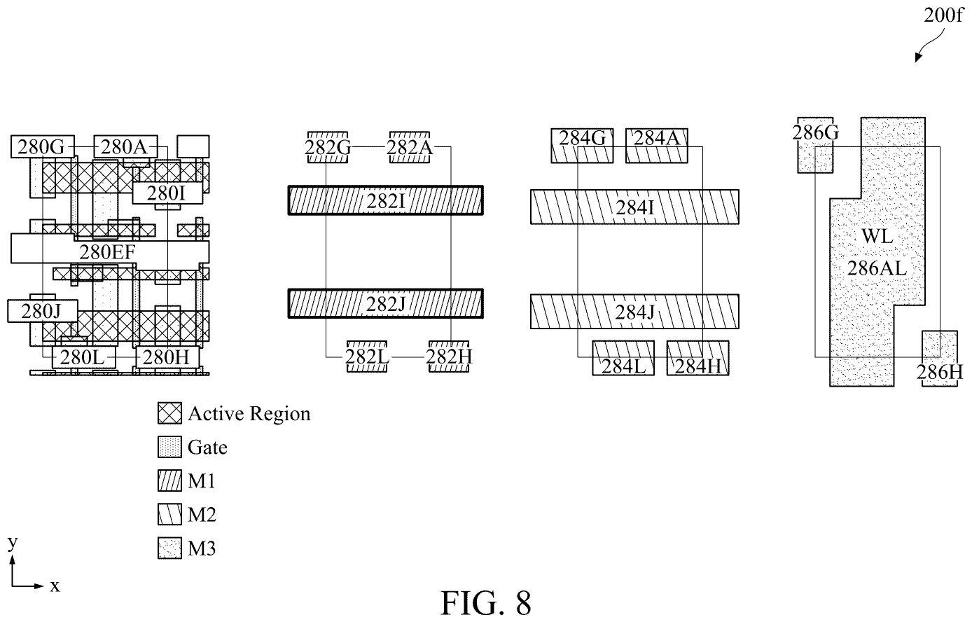

FIG. 8 schematically illustrates a SRAM cell 200f according to embodiments of the present disclosure. Particularly, FIG. 8 illustrates side-by-side layouts of the SRAM cell 200f in the M0, M1, M2, and M3 levels. The SRAM cell 200f is similar to the SRAM cell 200e except that in the SRAM cell 200f, VDD line is positioned in the M0 level. In the M0 level, the SRAM cell 200f includes a VDD line 280EF in place of the VDD landing pads 280E, 280F in the SRAM cell 200e. The VDD line 280EF extends along the X-direction. In the M1 level, the bit line 282I and the bit line bar 282J are positioned side-by-side.

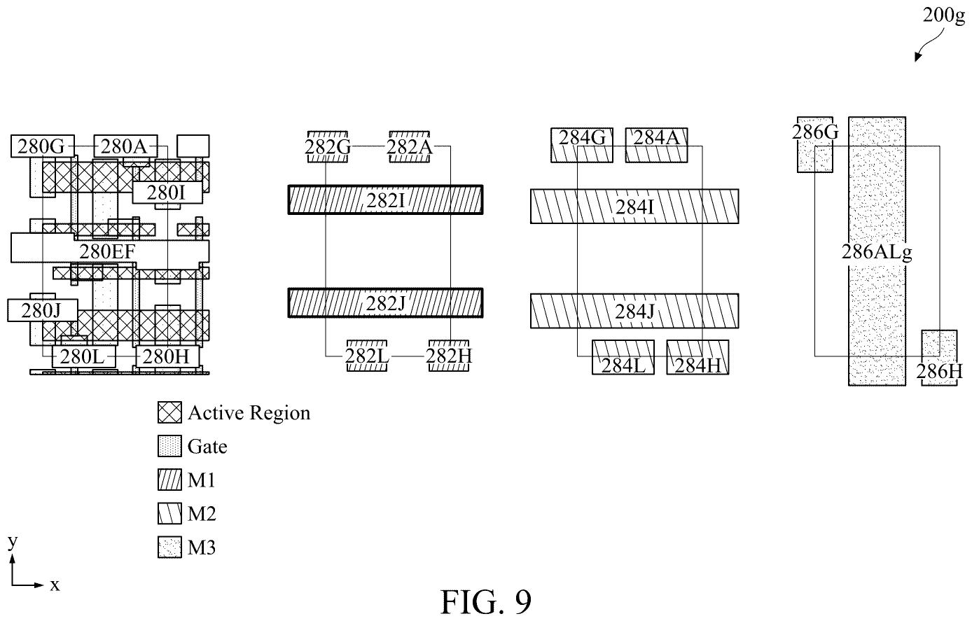

FIG. 9 schematically illustrates a SRAM cell 200g according to embodiments of the present disclosure. Particularly, FIG. 9 illustrates side-by-side layouts of the SRAM cell 200g in the M0, M1, M2, and M3 levels. The SRAM cell 200g is similar to the SRAM cell 200f except that the SRAM cell 200g includes word lines in straight lines. As shown in FIG. 9, in the M3 level, the SRAM cell 200g includes a word line 286ALg, which is a straight conductive line extends along the Y-direction.

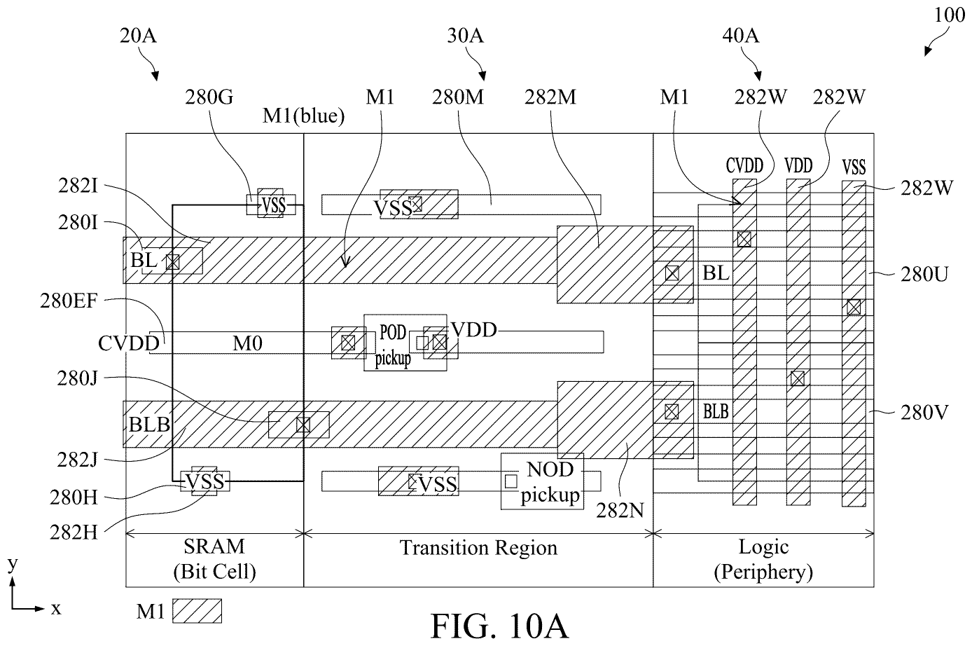

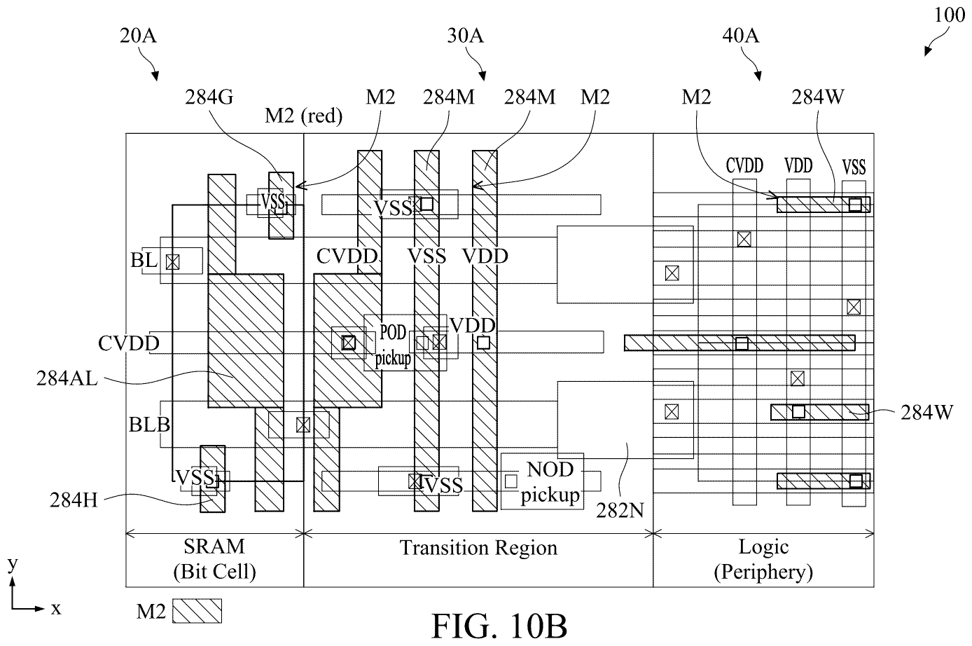

As discussed above, embodiments of the present disclosure provide a semiconductor device with SRAM cells having wrong way data lines, such as in the M1 level and in the M2 level. FIG. 10A illustrates the M0 level and M1 level of the layout of the semiconductor device 100, which includes a portion of the memory circuit region 20A, a portion of the logic circuit region 40A, and a transition region 30A disposed between the memory circuit region 20A and the logic circuit region 40A.

The M0 level, which is a first metal layer above the CO level, which includes gate contacts and source/drain contacts. Because source/drain regions in the semiconductor device 100 are formed along the X-direction, the M0 level, being the second MLI layer above the device layer, includes conductors extending along the X-direction, or the same direction of source/drain regions. For example, in the M0 level, the logic circuit region 40A includes a plurality of conductive lines, including a bit line 280U and a bit line bar 280V, extend in parallel along the X-direction. The memory circuit region 20A includes conductors, such as the landing pads 280 and the VDD line 280EF, extending along the X-direction. The transition region 30A also includes conductors 280M extending along the x-direction.

In some embodiments, the semiconductor device 100 includes conductive lines extending different directions in the M1 level. According to the design rules, the M1 level would include conductors along the Y-direction. The M1 level in the logic circuit region 40A, which follows the design rules, includes a plurality of conductive lines, for example conductive lines 282W, extending in parallel along the Y-direction. In some embodiments, the conductive lines 282W may include a CVDD line, a VDD line, and a VSS line. However, the M1 level in the memory circuit region 20A deviates from the design rules. The M1 level conductive lines in the memory circuit region 20A extending along the X-direction. In some embodiments, the conductors in the memory circuit region 20A, such as the bit line 282I and the bit line bar 282J, extend into the transition region 30A. In the transition region 30A, the bit line 282I and the bit line bar 282J are connected to landing pads 282M, 282N, which bridge over to the logic circuit region 40A. In some embodiments, the landing pads 282M, 282N connect the bit line 282I and the bit line bar 282J in the memory circuit region 20A to the bit line 280U and bit line bar 280V in the logic circuit region 40A through vias between the M1 level and the M0 level. In some embodiments, the landing pads 282M, 282N may be wider along the Y-direction than the bit line 282I and the bit line bar 282J.

FIG. 10B illustrates the M2 level of the layout of the semiconductor device 100. As shown in FIG. 10B, the semiconductor device 100 includes conductive lines extending different directions in the M2 level. According to the design rules, the M2 level would include conductors along the X-direction. The M2 level in the logic circuit region 40A, which follows the design rules, includes a plurality of conductive lines, for example conductive lines 284W, extending in parallel along the X-direction. However, the M2 level in the memory circuit region 20A deviates from the design rules. The M2 level conductive lines in the memory circuit region 20A extend along the Y-direction. In some embodiments, the conductors in the memory circuit region 20A, such as the word line 284AL, extend along the Y-direction. In some embodiments, the transition region 30A includes conductive lines 284M extending along the Y-direction. Not shown in FIG. 10B, the word lines 284AL in the memory circuit region 20A are connected to the logic circuit regions 40A at upper levels.

Various embodiments or examples described herein offer multiple advantages over the state-of-art technology. By positioning bit lines of a SRAM cell in the M1 level, embodiments of the present disclosure provide SRAM cells with reduced capacitance and resistance of the bit lines. Additionally, thickness of the IML layer, such as thickness of the M1 level, and/or width of the bit line and bit line bar may be reduced without increasing bit line capacitance or resistance. Various arrangements of the SRAM cells according to the present disclosure are compared to a reference SRAM cell having a bit line, a bit line bar and a VDD line formed in the M0 level to demonstrate the benefits, as discussed below.

In a first example, a first SRAM cell according to the present disclosure has a bit line, a bit line bar, and a VDD line formed in the M1 level without increasing the thickness of the M1 level. It has been observed that the bit line capacitance in the first SRAM cell has been reduced for about 1% and the bit line resistance in the first SRAM cell has been reduced in a range between about 40% to about 60%.

In a second example, a second SRAM cell according to the present disclosure has a bit line, a bit line bar, and a VDD line formed in the M1 level wherein the M1 level has a thickness reduction in a range between about 10% and about 15%. It has been observed that the bit line capacitance in the second SRAM cell has been reduced in a range between about 3% and about 5% and the bit line resistance in the second SRAM cell has been reduced in a range between about 20% to about 40%.

In a third example, a third SRAM cell according to the present disclosure has a bit line and a bit line bar formed in the M1 level while the VDD line remains in the M0 level. The M1 level has a thickness reduction in a range between about 10% and about 15%. It has been observed that the bit line capacitance in the third SRAM cell has been reduced in a range between about 6% and about 10% and the bit line resistance in the second SRAM cell has been reduced in a range between about 20% to about 40%.

In a fourth example, a fourth SRAM cell according to the present disclosure has a bit line and a bit line bar formed in the M1 level. The M1 level has a thickness reduction in a range between about 10% and about 15%. The bit line and bit line bar have a width reduction in a range between about 6% and 10% from widths of the bit line and the bit line bar in the reference SRAM cell. It has been observed that the bit line capacitance in the third SRAM cell has been reduced in a range between about 10% and about 15% and the bit line resistance in the second SRAM cell has been reduced in a range between about-1% to about +1%.

It will be understood that not all advantages have been necessarily discussed herein, no particular advantage is required for all embodiments or examples, and other embodiments or examples may offer different advantages.

Some embodiments of the present disclosure provide a semiconductor device, comprising a device layer having transistors formed therein, wherein the transistors include source/drain regions aligned along a first direction, and gate structures extending along a second direction; and a multilayer interconnect (MLI) formed over the device layer, wherein the MLI comprises: a contact level formed immediately on the device layer, wherein the contact level comprises gate contacts and source/drain contacts; a M0 level formed on the contact level, wherein the M0 level comprises a bit line landing pad, a bit line bar landing pad, and a word line landing pad; and a M1 level formed on the M0 level, wherein the M1 level comprises a bit line and a bit line bar extending along the first direction, the bit line is connected to the bit line landing pad in the M0 level, and the bit line bar is connected to the bit line bar landing pad in the M0 level.

Some embodiments of the present disclosure provide a semiconductor device, comprising: a substrate including a logic circuit region and a memory circuit region; a device layer formed on the substrate and extending over the logic circuit region and the memory circuit region of the substrate; and a multilayer interconnect (MLI) formed over the device layer, wherein the MLI comprises a first MLI layer comprising: first conductive lines in the memory circuit region; and second conductive lines in the logic circuit region, wherein the first conductive lines extend along a first direction, and the second conductive lines extend along a second direction different from the first direction.

Some embodiments of the present disclosure provide a method comprising: forming a semiconductor device comprising: a device layer on a memory circuit region and a logic circuit region of a substrate, wherein the device layer includes transistors having source/drain regions aligned along a first direction and gate structures along a second direction; a contact layer over the device layer, wherein the contact layer includes gate contact features and source/drain contact features; a first interconnect layer on the contact layer, wherein the first interconnect layer includes landing pads over the memory circuit region; and a second interconnect layer on the first interconnect layer, wherein the second interconnect layer includes first conductive lines in the memory circuit region, second conductive lines in the logic circuit region, wherein the first conductive lines extend along the first direction, and the second conductive lines extend along the second direction.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a device layer having transistors formed therein, wherein the transistors include source/drain regions aligned along a first direction, and gate structures extending along a second direction; and
a multilayer interconnect (MLI) formed over the device layer, wherein the MLI comprises:
a contact level formed immediately on the device layer, wherein the contact level comprises gate contacts and source/drain contacts;
a M0 level formed on the contact level, wherein the M0 level comprises a bit line landing pad, a bit line bar landing pad, and a word line landing pad; and
a M1 level formed on the M0 level, wherein the M1 level comprises a bit line and a bit line bar extending along the first direction, the bit line is connected to the bit line landing pad in the M0 level, and the bit line bar is connected to the bit line bar landing pad in the M0 level.

2. The semiconductor device of claim 1, wherein the MLI further comprises:
a M2 level formed over the M1 level, wherein the M2 level comprises a first word line extending along the second direction.

3. The semiconductor device of claim 2, wherein the M1 level further comprises: a VDD line extending along the first direction.

4. The semiconductor device of claim 2, wherein the M0 level further comprises: a VDD line extending along the first direction.

5. The semiconductor device of claim 2, wherein the MLI further comprises:
a M3 level formed over the M2 level, wherein the M3 level comprises a second word line extending along the second direction.

6. The semiconductor device of claim 1, wherein the MLI further comprises:
a M2 level formed over the M1 level, wherein the M2 level comprises a second bit line, a second bit line bar extending along the first direction, and a second word line landing pad.

7. The semiconductor device of claim 6, wherein the MLI further comprises:
a M3 level formed over the M2 level, wherein the M3 level comprises a second word line extending along the second direction and connected to the second word line landing pad in the M2 level.

8. A semiconductor device, comprising:
a substrate including a logic circuit region and a memory circuit region;
a device layer formed on the substrate and extending over the logic circuit region and the memory circuit region of the substrate; and
a multilayer interconnect (MLI) formed over the device layer, wherein the MLI comprises a first MLI layer comprising:
first conductive lines in the memory circuit region; and
second conductive lines in the logic circuit region, wherein the first conductive lines extend along a first direction, and the second conductive lines extend along a second direction different from the first direction.

9. The semiconductor device of claim 8, wherein the first conductive lines are memory bit lines for SRAM cells in the memory circuit region.

10. The semiconductor device of claim 9, wherein the MLI comprises a second MLI layer disposed between the device layer and the first MLI layer, wherein the second MLI layer includes bit line landing pads in the memory circuit region, and logic bit lines in the logic circuit region, the bit line landing pads are in connection with the first conductive lines, and the logic bit lines extends along the first direction.

11. The semiconductor device of claim 10, wherein the substrate further comprises a transition region disposed between the memory circuit region and the logic circuit region, the first MLI layer comprises transition landing pads in the transition region, and the memory bit lines extend into the transition region to connect with the transition landing pads.

12. The semiconductor device of claim 11, wherein the transition landing pads are connected to the logic bit lines in the second MLI layer by vias between the first MLI layer and the second MLI layer.

13. The semiconductor device of claim 10, wherein the MLI comprises a third MLI layer disposed above the first MLI layer, wherein the third MLI layer comprises:
third conductive lines in the memory circuit region; and
fourth conductive lines in the logic circuit region, wherein the third conductive lines extend along the second direction, and the fourth conductive lines extend along the first direction.

14. The semiconductor device of claim 13, wherein the third conductive lines are word lines for the SRAM cells in the memory circuit region.

15. The semiconductor device of claim 12, wherein the MLI comprises a third MLI layer disposed above the first MLI layer, wherein the third MLI layer comprises:
third conductive lines in the memory circuit region; and
fourth conductive lines in the logic circuit region, wherein the third conductive lines and the fourth conductive lines extend along the first direction, and the third conductive lines are second bit lines for the SRAM cells in the memory circuit region.

16. A method, comprising:
forming a semiconductor device comprising:
a device layer on a memory circuit region and a logic circuit region of a substrate, wherein the device layer includes transistors having source/drain regions aligned along a first direction and gate structures along a second direction;
a contact layer over the device layer, wherein the contact layer includes gate contact features and source/drain contact features;
a first interconnect layer on the contact layer, wherein the first interconnect layer includes landing pads over the memory circuit region; and
a second interconnect layer on the first interconnect layer, wherein the second interconnect layer includes first conductive lines in the memory circuit region, second conductive lines in the logic circuit region, wherein the first conductive lines extend along the first direction, and the second conductive lines extend along the second direction.

17. The method of claim 16, wherein the semiconductor device further comprises a third interconnect layer on the second interconnect layer, wherein the third interconnect layer includes third conductive lines in the memory circuit region, fourth conductive lines in the logic circuit region, wherein the third conductive lines extend along the second direction, and the fourth conductive lines extend along the first direction.

18. The method of claim 17, wherein the first conductive lines are bit lines for memory cells in the memory circuit region, and the third conductive lines are word lines for the memory cells in the memory circuit region.

19. The method of claim 18, wherein the semiconductor device further comprising: fifth conductive lines along the first direction in the first interconnect layer, wherein the fifth conductive lines include VDD lines in the memory circuit region.

20. The method of claim 19, wherein the fifth conductive lines further include logic bit lines in the logic circuit region.
